(19) United States
(12) Patent Application Publication
(10) Pub. No.: US 2009/0165703 A1
(43) Pub. Date: Jul. 2, 2009

(54) Silicon ingot fabrication

(75) Inventors: Paul Maloney, Los Gatos, CA (US); Carlos Dizon, Newark, CA (US)

Correspondence Address: HAVERSTOCK & OWENS LLP, 162 N WOLFE ROAD, SUNNYVALE, CA, 94086, US

(73) Assignee: West Coast Quartz Corporation

(21) Appl. No.: 12/006,351

(22) Filed: Dec. 31, 2007

(51) Int. Cl. C30B 9/00; C30B 35/00; H01R 43/00

(52) U.S. Cl. 117/81; 117/223; 29/825

(57) ABSTRACT

A method of and apparatus for growing single crystal silicon ingots is disclosed. The apparatus includes a charge structure with one or more charge units that are substantially multi-crystalline or single crystal silicon. The silicon charge structure is preferably coupled to a single crystal seed structure that can be used to grow a silicon ingot after the silicon charge unit is melted into a quartz growing crucible. The silicon charge units can be linked together through silicon linking structures that are threaded into or otherwise secured to the silicon charge units. In accordance with the method of the invention a crucible holding poly-silicon stock and the silicon charge structure are isolated within a process chamber. A process melt is formed and charged with the silicon charge structure, and a silicon ingot is formed without exposing the crystal growing chamber to an outside environment.

### FIELD OF THE INVENTION

The present invention relates to methods of and systems for fabricating silicon ingots. More particularly, the present invention relates to methods of and systems for fabricating silicon ingots using silicon charge structures for charging silicon process melts.

### BACKGROUND OF THE INVENTION

One process for producing single crystal silicon ingots, also referred to herein simply as silicon ingots, for the electronic industry is the Czochralski crystal growing process. In the Czochralski crystal growing process, pieces of polycrystalline silicon chunks, also referred to as polycrystalline feed stock, are loaded into a quartz crucible. The crucible is loaded into a furnace, which is sealed and evacuated. The polycrystalline silicon is melted under vacuum to form a process melt (liquid molten). Once the process melt has been stabilized, a single crystal silicon seed structure, also referred to herein as a silicon seed structure, having the proper crystallographic orientation is inserted into the melt, where the silicon seed structure is rotated by a cable apparatus. The silicon seed structure is slowly pulled out of the process melt to draw or pull a silicon ingot from the process melt. By adjusting the spin rate of the silicon seed structure and the rate that the silicon seed structure is pulled from or drawn from the melt, the diameter of the silicon ingot formed can be controlled. The volume of the silicon ingot that is formed is limited by the volume of the process melt. Ramping up the furnace or the crystal growing process or ramping down the furnace or furnace turn around process are time consuming and expensive. Therefore, there is a general need to maximize the productivity of the crystal growing process. Further, because of the current market demands for silicon feed stock materials and resulting cost associated with silicon feed stock materials, there is a need to maximize the use of silicon materials during the fabrication of silicon ingots.

### SUMMARY OF THE INVENTION

The present invention is directed to systems for and methods of growing single crystal silicon ingots, hereafter silicon ingots. In accordance with the embodiments of the invention, an apparatus for charging a crucible within an isolated crystal growing chamber comprises a silicon charge structure. The silicon charge structure is formed from, or includes, one or more silicon charge units formed from mono-crystalline silicon, multi-crystalline silicon, poly-silicon, or any combination thereof. The silicon charge unit is, for example, a portion of a silicon ingot formed from a previous process run. The silicon charge unit is not necessarily entirely single crystal and can have physical and structural flaws, such as slip, lost structure, and a resistivity that is outside of tolerances for use in wafer fabrication. In fact, the silicon charge unit can include a silicon ingot or a portion of a silicon ingot formed during a failed attempt to grow a single crystal silicon ingot and/or a tail portion of a single crystal silicon ingot, such as tail-end portions of silicon ingots that are unsuitable for wafer processing. The silicon charge structure can also include multi-crystalline silicon and poly-silicon, such as described below.

In accordance with the embodiments of the invention the silicon charge structure includes a silicon seed structure that is preferably attached to one of the silicon charge units and can be used to grow or draw a silicon ingot from a process melt after topping off or charging the process melt with the silicon charge unit. The single crystal seed structure can be attached to the silicon charge structure by any suitable mechanism, including a keyhole mechanism such as described in U.S. Pat. No. 6,835,247, titled “ROD REPLENISHING SYSTEM FOR USE IN SINGLE CRYSTAL SILICON PRODUCTION,” the contents of which are hereby incorporated by reference, or a thread mechanism, such as described in detail below. An apparatus in accordance with the embodiments of the invention can include a suspension mechanism, such as a chuck for attaching to the silicon seed structure and a cable for suspending the silicon seed structure and the silicon charge structure over a crucible, such that the silicon charge structure can be lowered into the process melt to top-off or charge the process melt.

In accordance with further embodiments of the invention, a silicon charge structure includes one or more silicon charge units formed from virgin poly-silicon, grown multi-crystalline silicon, grown mono-crystalline silicon, or any combination thereof that is attached to a silicon seed structure through a thread mechanism. In accordance with the embodiments of the invention the silicon seed structure includes thread features that thread, bolt or screw into the silicon charge structure with complementary thread features.

In accordance with still further embodiments of the invention, a silicon charge structure includes any number of discrete or individual silicon charge structure units that are linked together in a “chain-like” fashion through an appropriate number of silicon linking structures. The silicon charge units can be formed from virgin poly-silicon, grown multi-crystalline silicon, grown mono-crystalline silicon or any combination thereof. The silicon linking structures can be silicon rod structures (such as silicon seed structures) that are threaded into the silicon charge units or otherwise secured to the silicon charge units. For example, the charge units are linked together in a chain-like fashion through keyhole mechanisms, similar to those described in the U.S. Pat. No. 6,835,247 referenced previously, thread mechanisms, such as described below or any other suitable mechanisms.

A linking structure, in accordance with a preferred embodiment of the invented is threaded on opposed ends, such that the linking structure is capable of being screwed into adjacent silicon charge structure units with matched thread features to form a silicon charge structure.

In accordance with further embodiments of the invention an end silicon charge unit is attached to a modified silicon seed structure that can be used to pull, draw, grow or form a silicon ingot, such as described above and below. The modified silicon seed structure is preferably threaded on one or more ends, such that the silicon seed structure is capable of being screwed into the end charge unit with matched threaded features.

In accordance with the method of the present invention a process melt is formed in a crucible by melting an amount of poly-silicon feed stock within a crucible that is isolated within a process chamber or a crystal growing furnace. After a process melt is formed, one or more silicon charge units forming a silicon charge structure are melted into the process melt to top-off or charge the process melt, preferably without accessing the process chamber. The silicon charge structure can include the silicon charge units that are linked together through silicon linking structures in a chain-like fashion and also preferably includes a silicon seed structure attached to at least one of the silicon charge units. After the process melt is topped-off or charged with the one or more silicon charge units, the silicon seed structure is used to pull, draw, grow or otherwise form a silicon ingot without exposing the process chamber to an outside environment.

### BRIEF DESCRIPTION OF THE DRAWINGS

FIG. 1 shows a schematic representation of a crystal growing furnace, in accordance with the embodiments of the invention.

FIGS. 2A-B show schematic representations of a crucible with poly-silicon stock material therein before and after a meltdown process, respectively.

FIG. 3 shows a crystal growing furnace with a recharging feed tube, in accordance with the embodiments of the invention.

FIG. 4A is a cross-sectional representation of a silicon ingot, in accordance with the embodiments of the invention.

FIG. 4B shows a crucible with a bottom portion and residual process melt left over after the silicon ingot is grown.

FIGS. 4C-D show schematic representations of silicon charge units formed from a top and bottom portions of a silicon ingot, in accordance with the embodiments of the invention.

FIG. 5A shows a schematic representation of a silicon charge structure for charging a crucible, in accordance with the embodiments of the invention.

FIG. 5B shows a silicon seed crystal coupled to a silicon charge structure using a keyhole mechanism for charging a crucible, in accordance with the embodiments of the invention.

FIGS. 6A-B show cross-sectional views of a silicon seed structure configured to couple to a silicon charge unit through a thread mechanism, in accordance with the embodiments of the invention.

FIGS. 7A-B show modified silicon seed crystal structures with threaded ends configured to couple to an end of a silicon charge unit and a tapered or a notched end configured to couple to a chuck, in accordance with the embodiments of the invention.

FIGS. 8A-B show cross-sectional views of a silicon seed crystal configured to couple to a modified tail portion of a silicon ingot through a thread mechanism, in accordance with the embodiments of the invention.

FIG. 9 shows a silicon seed crystal configured to couple to a modified tail portion of a silicon ingot through a thread mechanism and suspended over a crucible for topping off or charging a process melt, in accordance with the embodiments of the invention.

FIG. 10A-C show a silicon charge structure formed from a plurality of silicon charge units that are coupled together in a chain-like fashion through a plurality of silicon linking structures, in accordance with the embodiments of the invention

FIG. 11 is a flow chart outlining steps for growing a silicon ingot, in accordance with a method of the present invention.

### DETAILED DESCRIPTION OF THE INVENTION

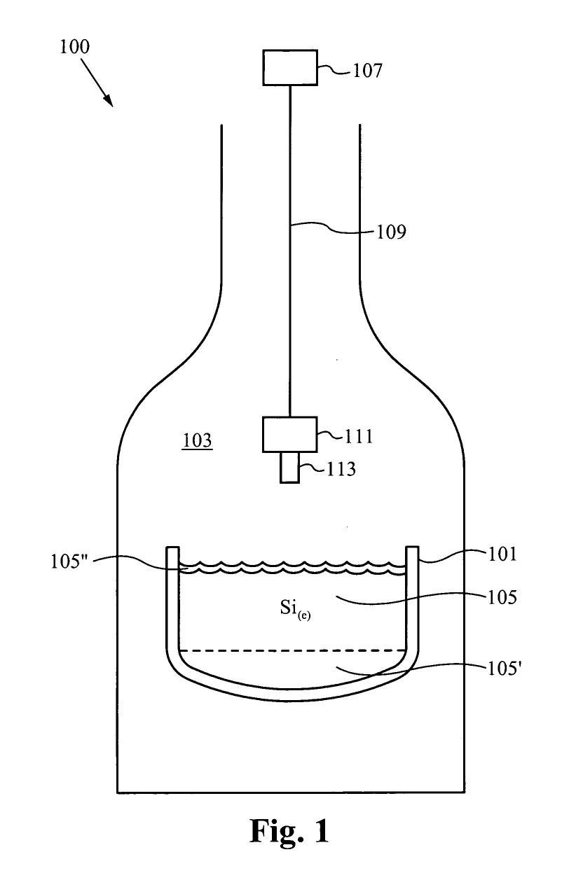

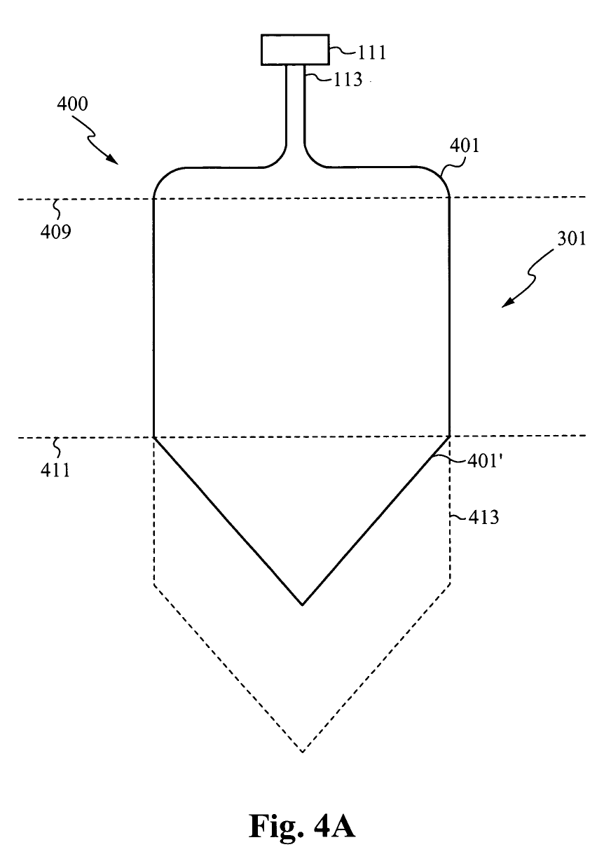

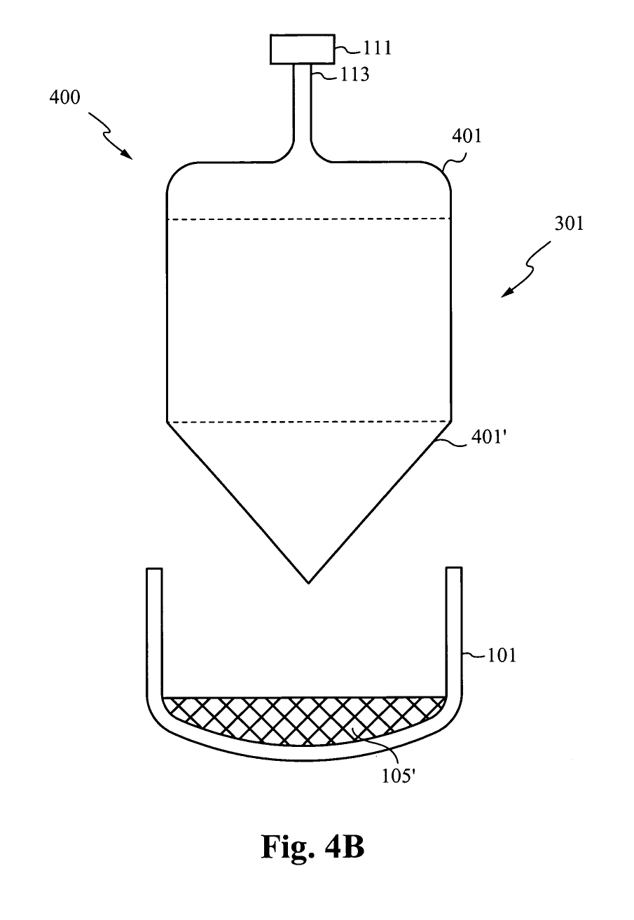

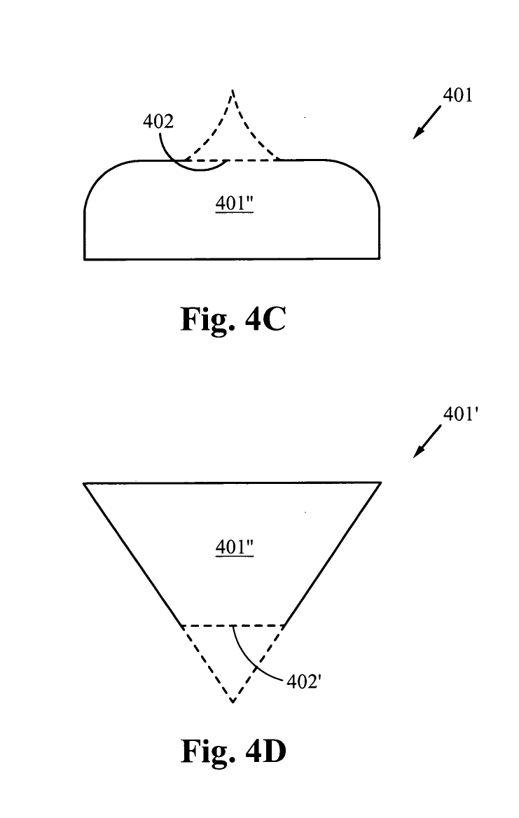

The present invention is directed to improved methods of and systems for growing silicon ingots. FIG. 1 shows a schematic representation of a crystal growing furnace 100. In operation, a process melt 105 is formed within a process chamber 103 of the crystal growing furnace 100. The process melt 105 is contained in a crucible 101 and has a liquid interface 105″ at or near the top portion of the process melt 105. A single crystal silicon seed crystal 113, hereafter referred to as a silicon seed crystal, is attached to a chuck 111 and is suspended over the process melt 105 through a cable assembly 109 that is attached to a rotary motor 107. The rotary motor 107 is configured to lower and raise the silicon seed crystal 113 as well as rotate the silicon seed crystal 113 at selected or controlled rates. In order to draw, pull or form a silicon ingot 400 (FIG. 4), the silicon seed crystal 113 is lowered into the liquid interface 105″ of the processes melt 105 and rotated at a controlled or selected rate. The silicon seed crystal 113 is slowly pulled up or raised from the process melt 105 as the silicon ingot 400 is formed. After the silicon ingot 400 is formed, the furnace is shut down, and the crucible 101 and a bottom portion 105′ of the process melt 105 are discarded.

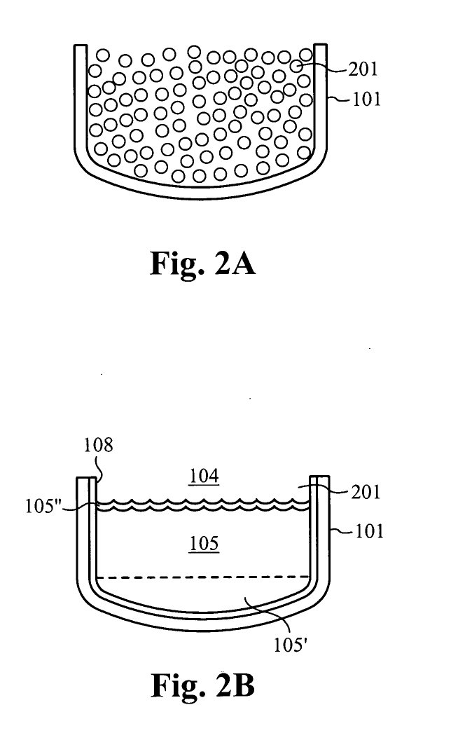

A major portion of the production costs associated with the fabrication of a silicon ingot 400, such as described above, are incurred during the setup and shut down of the crystal growing furnace 100. Other costs in the fabrication of the silicon ingot 400 include the cost of the crucible 101 and the cost of silicon feed stock material 201 (FIG. 2A) used to form the process melt 105.

FIGS. 2A-B will now be used to illustrate the formation of the process melt 105. To form the process melt 105, the crucible 101 is filled with pieces or chunks of silicon feed stock material 201, as shown in FIG. 2A. Referring to FIGS. 1 and 2A-B, with the crucible 101 in the process chamber 103 of the crystal growing furnace 100, the process chamber 103 is sealed and evacuated. After the crucible 101 and the silicon feed stock material 201 are isolated within the process chamber 103, they are heated to form the processes melt 105. The process melt 105 is maintained at controlled processing conditions until the process melt 105 has “stabilized,” which typically occurs over a time period of several hours such as, for example, ten hours. Because the silicon feed stock material 201 comes in chunks or pieces, the entire volume of the crucible 101 is not occupied by the process melt 105 that is formed. The top and unused volume 104 of the crucible 101 can account for twenty percent or more of the total volume of the crucible 101.

After the silicon ingot 400 (FIG. 4) is formed over a period of time, such as twenty hours, the crystal growing furnace 100 is shut down and cleaned. The shut down process takes several hours, such as ten hours or more. In a typical process run for forming a silicon ingot, the setup and shut down times can account for 50 percent of the production time.

As mentioned above, the crucible 101 and the bottom portion 105′ of the process melt 105 are both discarded after a single process run because the crucible 101 usually will deform and crack upon being cycled through heating and cooling generally required for removing a silicon ingot 400 from the furnace 100 after the silicon ingot 400 is grown. Even small structural deformations in the walls of the crucible 101 will result in turbulent flows of the process melt 105, resulting in crystal defects in the ingot 400 formed, thus making the silicon ingot 400 unsuitable for wafer fabrication used in electronic device manufacturing.

Since quartz crucibles, such as the crucible 101, are expensive, it would be beneficial to maximize the lifetime of the crucible 101, such that the crucible 101 could be used for multiple process runs. To this end, quartz crucibles have been made with a special inner surface coating 108. Unfortunately, a crucible 101 with the special inner surface coating 108 is typically much more expensive than a crucible 101 without the special inner surface coating 108. Further, quartz crucibles with the special inner surface coatings have been shown to have only limited success for use in multiple process runs. This is partially due to the astringent purity requirements for growing the silicon ingot 400 and the difficulties associated with keeping contaminants out of the crucible 101 and the bottom portion of the melt 105′ during the shut down process of the furnace 100.

Referring to FIG. 2B, the volume of the process melt 105, minus the bottom portion 105′ of the process melt 105 accounts for the portion of the process melt 105 that can be used to form the silicon ingot 400 (FIG. 4A). If the top volume portion 104 of the quartz crucible 101 could be filled with the process melt 105, then the volume of the silicon ingot 400 that is formed 400 could be increased by an estimated twenty percent, as indicated by the dotted line 413 (FIG. 4A), and accordingly increase the output of the crystal growing process by approximately twenty percent. In addition to all the aforementioned shortcomings in the crystal growing process described, the cost of silicon feed stock material 201 has escalated as the demand for silicon for use in the fabrication of solar cells and semiconductor components have increased. For all of these reasons there is a continued need to minimize costs and waste of raw materials and/or maximize the output during silicon ingot fabrication processes.

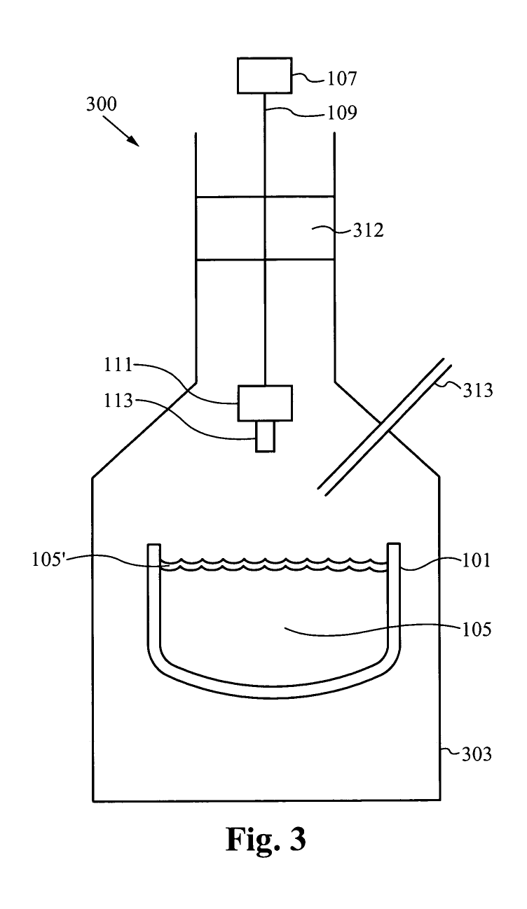

One approach to optimizing the output during silicon ingot fabrication and maximizing the output from the quartz crucible 101 is referred to as semi-continuous silicon crystal growth processes. Referring to FIG. 3, in semi-continuous silicon crystal growth processes, a silicon growing furnace 300 is fitted with a feed tube 313 that accesses the process chamber 303 of the crystal growing furnace 300. Similar reference numbers refer to the same element throughout this Application. In operation, silicon feed stock 201 is dropped into the process melt 105 through the feed tube 313 after the process melt 105 is formed in the crucible 101 to “top-off” or charge the processes melt 105 and thus utilize the entire volume of the quartz crucible 101. Further, the crystal growing furnace 300 can be equipped with an isolation chamber 312 that can be used to remove the silicon ingot 400 (FIG. 4) after it is formed. After the silicon ingot 400 is removed through the isolation chamber 312, the quartz crucible 101 can be replenished with poly-silicon feed stock 201 and a second silicon ingot can be formed. There are a number of shortcomings with semi-continuous crystal growth processes described above. The feed tube 313 and/or the isolation chamber 312 are a source of impurities and contaminants that enter into the process chamber 303 and contaminate the process melt 105 each time the process chamber 303 is accessed, which can lead to poor silicon crystal quality and failed process runs. Further, there are a large number of crystal growing furnaces in operation that are not equipped with feed tubes, such as 313, or isolation chambers, such as 312, and/or are not manufactured to support such features. Retro-fitting these furnaces can be expensive and often the retro-fitted crystal growing furnaces do not work as intended.

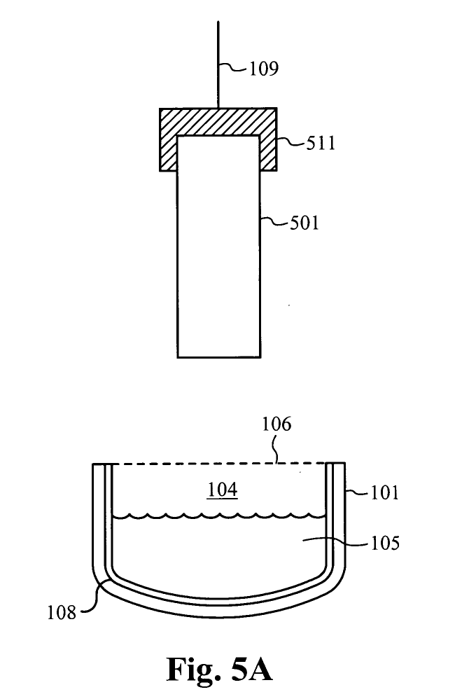

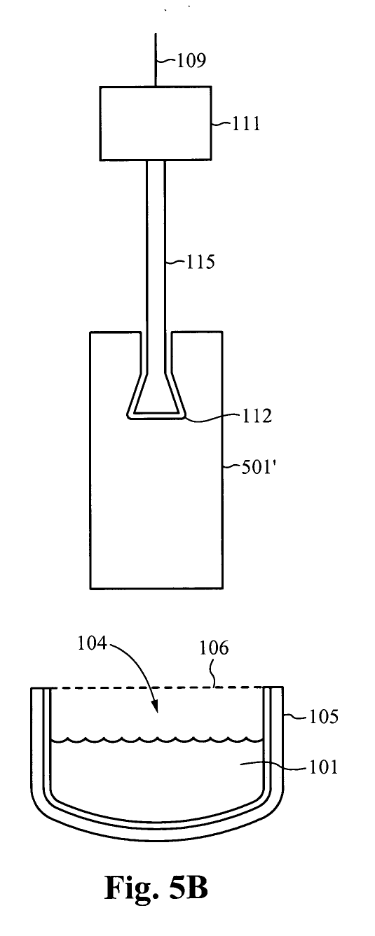

Another alternative is to use a poly-silicon charge rod 501, such as shown in FIG. 5A. Methods of and systems for using poly-silicon charge rods is described in the U.S. Pat. No. 6,835,247, titled “ROD REPLENISHING SYSTEM FOR USE IN SINGLE CRYSTAL SILICON PRODUCTION,” referenced previously. In accordance with these methods, one or more poly-silicon charge rods 501 are coupled to a modified chuck 511 that is attached to the cable assembly 109. The one or more poly-silicon charge rods 501 are lowered into the process melt 105 to top off 106 the process melt 105 and thus use the top volume portion 104 of the crucible 101. The modified chuck 511 and cable assembly 109 are then raised and the modified chuck 511 is changed out with a standard chuck 111 through an isolation chamber 312 (FIG. 3).

Now referring to FIGS. 3 and 5A, after the modified chuck 511 is changed out with a standard chuck 111, a silicon seed crystal 113 is attached to the standard chuck 111 and is lowered into the process melt 105 with the cable assembly 109 and a silicon ingot 400 (FIG. 4A) is formed from the process melt 105, such as described above.

Referring now to FIG. 5B, in order to reduce the number of process steps for growing silicon ingots, an improved process has been developed, whereby a key structure 115 is configured to have similar dimensions to that of a silicon seed crystal, such that it can be replaced or changed out with the silicon seed crystal 113, such as described below. The key structure 115 is configured to hold or secure a modified poly-silicon charge rod 501′ through a matched keyhole feature 112. In accordance with this improved method, one or more modified poly-silicon charge rods 501′ are held to the chuck 111 through one or more corresponding key structures 115. The one or more modified poly-silicon charge rods 501′ are lowered into the process melt 105 using the cable assembly 109 to top off or charge 106 the process melt 105 and use the top volume portion 104 of the quartz crucible 101. The chuck 111 and the cable assembly 109 are then raised and a silicon seed crystal 113 is attached to the chuck 111 through the isolation chamber 312. The silicon seed crystal 111 is then lowered into the process melt 105 using the cable assembly 109 and the silicon ingot 400 (FIG. 4) is formed from the process melt 105, such as described above.

While the improved method described above eliminates the step of having to change out the modified chuck 511 with the chuck 111, the method still has a number of shortcomings. For example, the method still requires the use of an isolation chamber 312, which can introduce contaminants into the process melt 105 and lead to failed process runs. Further, this method cannot be used with a large number of crystal growing furnaces that are currently operating in the field and which do not have an isolation chamber. Also the modified poly-silicon charge rods 501′ are expensive and topping off or charging the quartz crucible 101 with multiple charge rods through a single charging step is complicated. Specifically, a “chandelier-like” chuck assembly is required to suspend the silicon charge rods over the process melt 105.

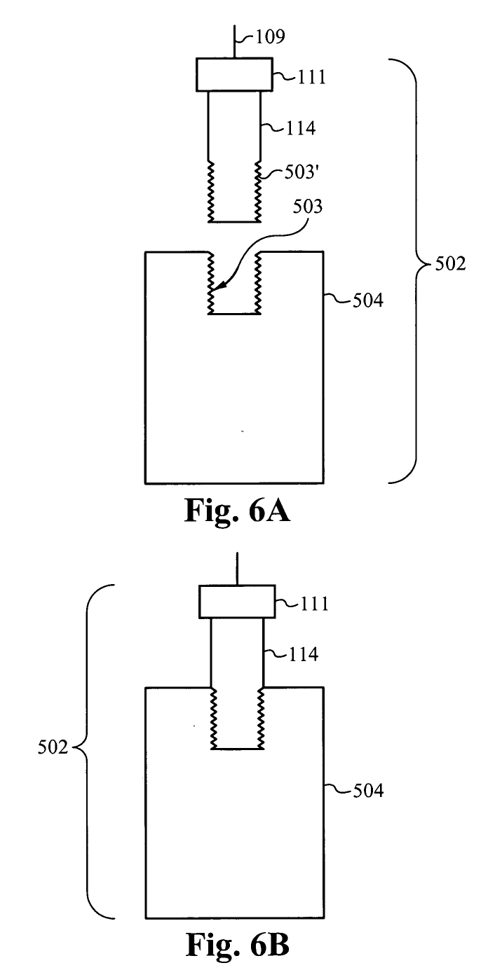

In accordance with the present invention, an apparatus includes a silicon charge structure 502, such as shown in FIGS. 6A-B. The silicon charge structure 502 includes a silicon charge unit 504 that is formed from silicon. Silicon herein means mono-crystalline silicon or single crystal silicon, multi-crystalline silicon or silicon with a number of crystalline regions and poly-silicon or amorphous silicon. Silicon charge units and linking structures, such as described below, are formed from mono-crystalline silicon, multi-crystalline silicon, poly-silicon and any combination thereof.

The apparatus further includes a silicon seed structure 114 that is configured to couple to or attach to a portion of the silicon charge unit 504. The silicon seed structure 114 can be configured to couple to or attach to the silicon charge unit 504 through any suitable mechanism, including a keyhole mechanism, such as described above with reference to FIGS. 5A-B.

Still referring to FIGS. 6A-B, the silicon seed structure 114 is preferably configured to couple to or attach to the silicon charge unit 504 through a thread mechanism, whereby thread features 503′ on the silicon seed structure 114 thread into matched thread features 503 on the silicon charge unit 504. Regardless of the mechanism used to couple the silicon seed structure 114 to the silicon charge unit 504, the silicon seed structure 114 is configured to attach to a chuck 111 with a cable assembly 109, such that the silicon charge unit 504 can be lowered into the process melt 105 to top-off or charge 106 the process melt 105 and, thus, use the top volume portion 104 of the quartz crucible 101 (FIGS. 2A and 5B).

In accordance with the method of the invention, after the silicon charge unit 504 is lowered into the process melt 105 to top-off or charge 106 the process melt 105, the silicon seed structure 114 then can be used to form a silicon ingot 400 from the process melt 105 without requiring the chuck 111 to be raised and/or accessing the process chamber 303 through the isolation chamber 312 (FIG. 3) to change out a chuck 109 or attach a silicon seed crystal to the chuck 109, such as described above.

Referring now to FIGS. 4A-D, in accordance with the embodiments of the invention, a silicon charge unit 401″, similar to the charge unit structure 504 shown in FIGS. 6A-B, is formed from a bottom 401′ or top portion 401 of a silicon ingot 400 (FIG. 4) formed in a previous process run. The silicon charge unit 401″ is formed by removing tapered portions of the bottom 401′ or top portion 401 of a silicon ingot 400 as indicated by the dotted lines 402′ and 402, respectively. Typically the bottom 401′ and the top portion 401 are cut from the silicon ingot 400, as indicated by the dotted lines 411 and 401 and the body portion 301 of the silicon ingot 400 is used for making wafers

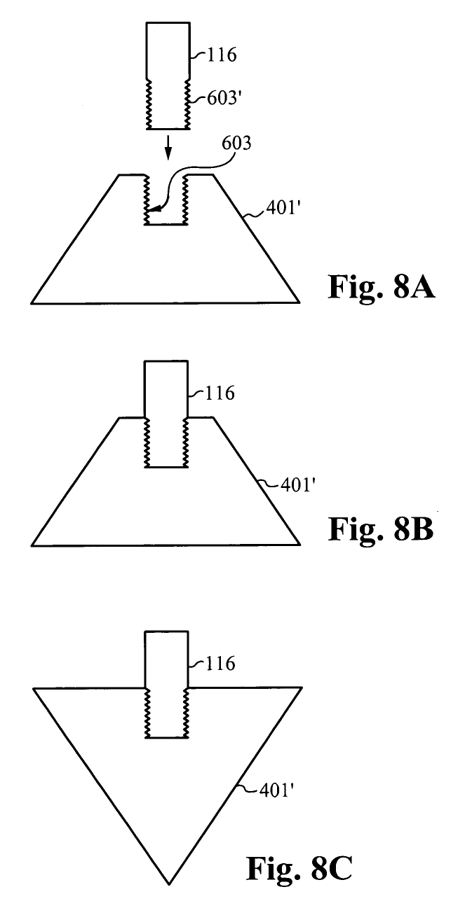

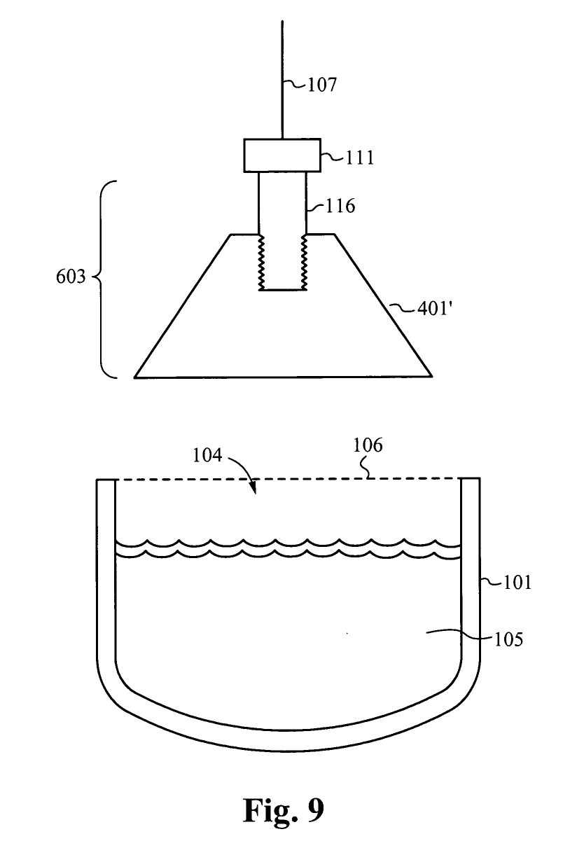

Now referring to FIGS. 8A-B, in accordance with the embodiments of the invention a silicon seed structure δ 16 can be fashioned or modified to have thread features 603′. In addition to removing tapered portions of the bottom 401′ or top portion 401 of a silicon ingot 400, the silicon charge unit 401″ is fashioned with matched thread features 603. In use, the silicon seed structure 116 is threaded or screwed into the matched thread features 603 of the silicon charge unit 401″ and as shown in FIGS. 8B and 9. The charge structure 603 formed from the silicon seed structure 116 and the silicon charge unit 401″ can then be attached to a chuck 111 with a cable assembly 107 within a process chamber 303 (FIG. 1). The silicon charge unit 401″ is then used to top-off or charge 106 the process melt 105 to use top volume portion 104 of the quartz crucible 101, as described previously. The silicon seed structure 116 can then be used to pull, draw or grow a silicon ingot 400 without requiring the chuck 111 to be raised and/or requiring the process chamber 303 to be accessed or exposed to an outside environment through, for example, the isolation chamber 312 (FIG. 3).

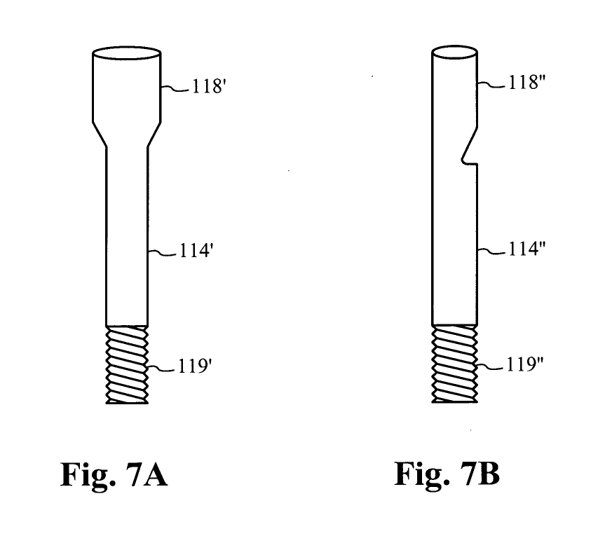

A silicon seed structure in accordance with embodiments of the invention can have any number of different designs. As shown in FIG. 7A, for example, a modified silicon seed structure 114′ can have a tapered end 118′ for attaching to a chuck 111 and a threaded feature 119′ for threading into a silicon charge unit 401″ formed form a bottom 401′ or top portion 401 of a silicon ingot 400. Alternatively, as shown in FIG. 7B, a modified silicon seed structure 114″ can have a notched end 118″ for attaching to a chuck 111 and a threaded feature 119″ for threading into a silicon charge unit 401″ formed form a bottom 401′ or top portion 401 of a silicon ingot 400 (FIG. 4). It will be clear to one skilled in the art from the discussion above and below that a modified silicon seed structure can have any number of configurations and can be configured to couple to silicon charge units through any number of mechanisms.

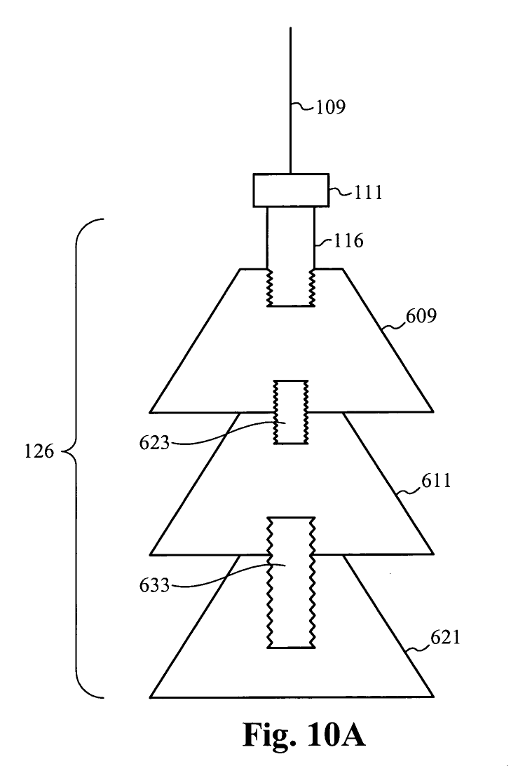

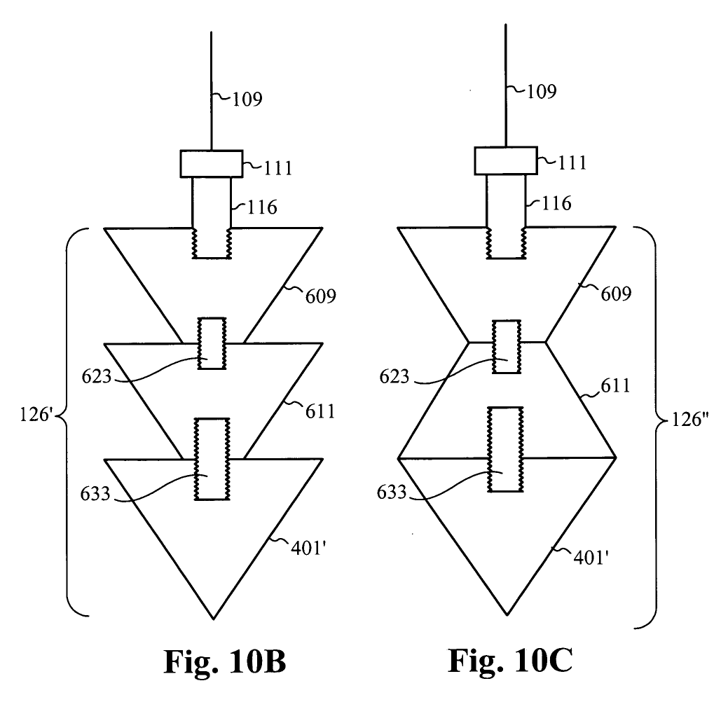

Referring now to FIG. 10A, in accordance with still further embodiments of the invention a silicon charge structure 126 includes a plurality of silicon charge units 609, 611 and 621 that are linked together in a chain-like fashion through a plurality of silicon linking structures 623 and 633. The silicon linking structures 623 and 633 are formed from mono-crystalline silicon, multi-crystalline silicon, poly-silicon, or any combination thereof and can link the plurality of silicon charge units 609, 611, 621 through any suitable structure with geometric features that couple adjacent pairs (609, 611 and 611, 621) of the silicon charge units 609, 611, 621 together, including keyhole features and thread features, such as described above. Preferably, the silicon charge structure 126 includes a modified single crystal silicon seed structure 116 that is threaded into or attached to an end silicon charge unit 609, such that the silicon charge structure 126 can be attached to the chuck 111 through the single crystal silicon seed structure 116. Accordingly, the single crystal silicon seed structure 116 can be used to pull or draw a silicon ingot 400 after charging the process melt 105 with the silicon charge units 609, 611 and 621 without accessing the process chamber 303 (FIG. 3). The silicon charge units 609, 611 and 621 are preferably formed from modified bottom or top portions of silicon ingots formed in previous process runs, such as described above with respect to the silicon charge unit 401″.

Referring now to FIG. 10B, in accordance with still further embodiments of the invention a silicon charge structure 126′ includes a plurality of silicon charge units 609, 611 and 621 that are linked together in a chain-like fashion through a plurality of silicon linking structures 623 and 633, such as described above. However, the plurality of silicon charge units 609, 611 and 621 in this configuration are linked with the with tapered ends of the silicon charge units 609, 611 and 621 facing downwards and in the opposite direction to that of the silicon charge units 609, 611 and 621 shown in FIG. 10A. Again, silicon linking structures 623 and 633 are formed from mono-crystalline silicon, multi-crystalline silicon, poly-silicon, or any combination thereof and can link the plurality of silicon charge units 609, 611, 621 through any suitable structure with geometric features that couple adjacent pairs (609, 611 and 611, 621) of the silicon charge units 609, 611, 621 together, such as described above.

Referring now to FIG. 10C, in accordance with yet further embodiments of the invention a silicon charge structure 126″′ includes a plurality of silicon charge units 609, 611 and 621 that are linked together in a chain-like fashion through a plurality of silicon linking structures 623 and 633, such as described above. However, the plurality of silicon charge units 609, 611 and 621 in this configuration are linked with the with tapered ends of the silicon charge units 609, 611 and 621 facing in alternating upward, downward or other directions. Again, silicon linking structures 623 and 633 are be formed from mono-crystalline silicon, multi-crystalline silicon, poly-silicon, or any combination thereof and can link the plurality of silicon charge units 609, 611, 621 through any suitable structure with geometric features that couple adjacent pairs (609, 611 and 611, 621) of the silicon charge units 609, 611, 621 together, such as described above.

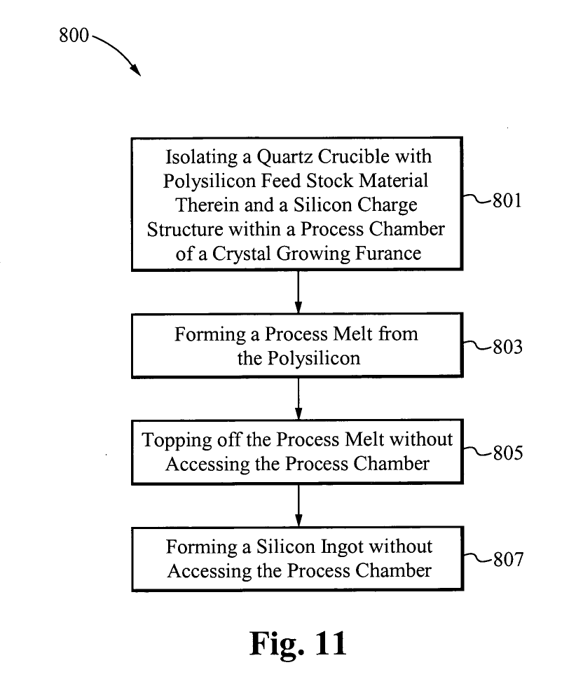

FIG. 11 shows a flow chart diagram 800 outlining the steps for charging a crucible with a charge structure and forming a silicon ingot, in accordance with a method of the present invention. In the step 801, a quartz crucible holding silicon feed stock material is isolated within a process chamber of a crystal growing furnace, as described in detail above. After, the crucible with silicon feed stock is isolated within the process chamber in the step 801, in the step 803 a process melt is formed by, for example, heating the crucible and the poly-silicon to a temperature sufficient to liquify the poly-silicon. After the process melt is formed in the step 803, in the step 805 the process melt is topped-off or charged with the silicon charge structure. The silicon charge structure preferably includes one or more charge units that are linked together in a chain-like fashion, such as described with respect to FIG. 10. Further, the charge structure includes a single crystal seed structure that is attached to at least one of the charge units. After the process melt is topped off or charged in the step 805, a silicon ingot is pulled from the process melt using the single crystal seed structure. Preferably, the charge structure is isolated within the process chamber of the crystal growing furnace at the same time that the crucible, and the silicon feed stock is isolated within the process chamber, such that the process chamber is not accessed, opened or exposed to an outside environment during the steps 803-807.

The present invention addresses a number of the shortcomings of the prior art methods. The method of the present invention can be used with crystal growing furnaces that are not equipped with feed tubes or isolation chambers, reduces contaminants in the process melt that can result from accessing the process chamber to charge the crucible, makes use of the scrap portions of silicon ingots which are generally free from contaminants, increases crystal output capacity per furnace and reduces cycle time per salable/usable silicon crystal kilogram.

The present invention has been described in terms of specific embodiments incorporating details to facilitate the understanding of the principles of construction and operation of the invention. As such, references, herein to specific embodiments and details thereof are not intended to limit the scope of the claims appended hereto. It will be apparent to those skilled in the art that modifications can be made in the embodiments chosen for illustration without departing from the spirit and scope of the invention.

What is claimed is:

1. An apparatus for charging a crucible within an isolated crystal growing chamber, the apparatus comprising:
a) a silicon charge structure comprising mono-crystalline silicon; and
b) a modified silicon seed structure for attaching to a suspension mechanism of the crystal growing chamber, the modified silicon seed structure being coupled to the silicon charge structure.

2. The apparatus of claim 1, wherein the modified silicon seed structure is coupled to the silicon charge structure through a threaded mechanism, wherein the threaded mechanism includes threaded features on the modified silicon seed structure and matched threaded features on the silicon charge structure.

3. The apparatus of claim 1, wherein the modified silicon seed structure comprises mono-crystalline silicon.

4. The apparatus of claim 1, wherein the modified silicon seed structure comprises multi-crystalline silicon.

5. The apparatus of claim 1, wherein the silicon charge structure comprises a plurality of silicon charge units.

6. The apparatus of claim 5, wherein the plurality of silicon charge units are linked together through silicon linking structures.

7. The apparatus of claim 6, wherein the silicon linking structures are threaded into adjacent pairs of the plurality of silicon charge units.

8. The apparatus of claim 1, wherein the silicon charge structure comprises one or more portions of a previously grown silicon ingot.

9. An apparatus for charging a crucible within an isolated crystal growing chamber, the apparatus comprising:
a) a silicon charge structure; and
b) a modified silicon seed structure for attaching to a suspension mechanism of the crystal growing chamber, the modified silicon seed structure being coupled to the silicon charge structure, wherein the silicon charge structure includes at least a portion of a previously grown silicon ingot.

10. The apparatus of claim 9, wherein the silicon charge structure includes mono-crystalline silicon charge units.

11. The apparatus of claim 9, wherein the modified silicon seed structure is coupled to the silicon charge structure through a threaded mechanism, wherein the threaded mechanism includes threaded features on the modified silicon seed structure and matched threaded features on the silicon charge structure.

12. The apparatus of claim 9, wherein the modified silicon seed structure comprises mono-crystalline silicon.

13. The apparatus of claim 9, wherein the modified silicon seed structure comprises multi-crystalline silicon.

14. The apparatus of claim 9, wherein the silicon charge structure comprises a plurality of silicon charge units.

15. The apparatus of claim 14, wherein the plurality of silicon charge units are linked together through silicon linking structures.

16. The apparatus of claim 15, wherein the silicon linking structures are threaded into adjacent pairs of the plurality of silicon charge units.

17. An apparatus for charging a crucible for growing silicon ingots, the apparatus comprising:
a) a silicon charge structure comprising a plurality of silicon charge units linked together through silicon linking structures; and
b) a modified silicon seed structure coupled to the silicon charge structure for attaching the silicon charge structure to a suspension mechanism within a silicon crystal growing chamber.

18. The apparatus of claim 17, wherein at least one of the plurality of silicon charge units comprises mono-crystalline silicon.

19. The apparatus of claim 17, wherein the modified silicon seed structure is coupled to the silicon charge structure through a threaded mechanism, wherein the threaded mechanism includes threaded features on the modified silicon seed structure and matched threaded features on the silicon charge structure.

20. The apparatus of claim 17, wherein the silicon seed structure comprises mono-crystalline silicon.

21. The apparatus of claim 17, wherein the silicon seed structure comprises multi-crystalline silicon.

22. The apparatus of claim 17, wherein the plurality of silicon charge units are linked together through silicon linking structures.

23. The apparatus of claim 22, wherein the silicon linking structures are threaded into adjacent pairs of the plurality of silicon charge units.

24. An apparatus for charging a crucible for growing silicon ingots, the apparatus comprising:
a) a silicon charge structure comprising one or more tapered charge units; and
b) a modified seed structure coupled to the one or more tapered charge units for attaching the silicon charge structure to a suspension mechanism within a silicon crystal growing chamber.

25. The apparatus of claim 24, wherein each of the one or more tapered charge units comprises mono-crystalline silicon.

26. The apparatus of claim 24, wherein the modified seed structure is coupled at least one of the one or more tapered charge units through a threaded mechanism, wherein the threaded mechanism includes threaded features on the modified seed structure and matched threaded features on the one or more tapered charge units.

27. The apparatus of claim 24, wherein the seed structure comprises mono-crystalline silicon.

28. The apparatus of claim 24, wherein the seed structure comprises multi-crystalline silicon.

29. The apparatus of claim 24, wherein the silicon charge structure further comprises one or more silicon linking structures for coupling the one or more tapered charge units in a daisy chain fashion.

30. The apparatus of claim 29, wherein the one or more silicon linking structures comprise mono-crystalline silicon.

31. The apparatus of claim 29, wherein the one or more silicon linking structures comprise multi-crystalline silicon.

32. The apparatus of claim 29, wherein the one or more silicon linking structures couple the one or more tapered charge units in a daisy chain fashion through threaded features on the one or more silicon linking structures and matched threaded features on the one or more tapered charge units.

33. A method of making a charge structure, the method comprising:
a) forming a plurality of silicon charge units;
b) linking the plurality of charge units together in a daisy chain fashion to form an extended silicon charge structure; and
c) coupling a modified silicon seed structure to an end of the extended silicon charge structure, wherein the modified silicon seed structure is configured to couple to a suspension mechanism of a crystal growing chamber.

34. The method of claim 33, wherein forming a plurality of silicon charge units comprises growing a silicon ingot and removing an end portion of the silicon ingot.

35. The method of claim 33, wherein linking the plurality of silicon charge units together comprises threading silicon linking structures between adjacent pairs of the plurality of charge units.

36. The method of claim 33, wherein coupling a modified silicon seed structure to an end of the extended silicon charge structure comprises threading the modified silicon seed structure into the end of the extended silicon charge structure.

37. A method of charging a silicon crystal growing crucible, the method comprising:
a) melting poly-silicon feed stock in the silicon crystal growing crucible to form a first melt; and
b) combining a plurality of silicon charge units to the first melt to form a second melt, wherein the plurality of silicon charge units are coupled together in an extended daisy chain fashion.

38. The method of claim 37, wherein one or more of the plurality of silicon charge units comprise mono-crystalline silicon.

39. The method of claim 37, wherein one or more of the plurality of silicon charge units is a portion of a silicon ingot.

40. The method of claim 37, wherein one or more of the plurality of silicon charge units is tapered.

41. The method of claim 37, wherein the plurality of silicon charge units are coupled together through one or more silicon linking structures between adjacent pairs of the plurality of silicon charge units.

42. The method of claim 41, wherein the one or more silicon linking structures are threaded into the adjacent pairs of the plurality of silicon charge units.

43. The method of claim 37, wherein melting the poly-silicon feed stock and combining the plurality of silicon charge units are performed in an isolated crystal growing chamber without exposing the crystal growing chamber to an external environment.

44. A method of growing a silicon ingot, the method comprising:
a) isolating a crystal growing chamber comprising a crucible with poly-silicon feed stock therein;
b) melting the poly-silicon feed stock to form a silicon melt;
c) adding a mono-crystalline silicon charge structure coupled to a silicon seed structure into the silicon melt to top off the silicon melt in the isolated crystal growing chamber; and
d) growing the silicon ingot from the topped off silicon melt.

45. The method of claim 44, wherein the mono-crystalline silicon charge structure is coupled to a modified mono-crystalline seed structure.

46. The method of claim 45, wherein the modified mono-crystalline seed structure is threaded into the mono-crystalline silicon charge structure.

47. The method of claim 44, wherein the mono-crystalline silicon charge structure comprises a plurality of charge units that are linked together in a daisy chain fashion through silicon linking features.

48. The method of claim 47, wherein the silicon linking features are threaded into adjacent pairs of the plurality of charge units.

49. The method of claim 47, wherein the plurality of charge units are portions of previously grown silicon ingots.
